(19) United States
(12) Patent Application Publication
(10) Pub. No.: US 2017/0018712 A1
(43) Pub. Date: Jan. 19, 2017

(54) A METHOD OF PRODUCING A GRAPHENE LAYER

(71) Applicant: PHILIPS LIGHTING HOLDING B.V., Eindhoven (NL)

(72) Inventors: Adrianus Johannes Maria Giesbers, Eindhoven (NL); Abraham Rudolf Balkenende, Eindhoven (NL); Leendert Van Der Tempel, Eindhoven (NL)

(21) Appl. No.: 15/301,645

(22) PCT Filed: Mar. 26, 2015
(86) PCT No.: PCT/EP2015/056481

§ 371 Date: Oct. 3, 2016

(30) Foreign Application Priority Data
Apr. 4, 2014 (EP) 14163503.7

(51) Int. Cl. H01L 51/00; H01L 51/56; C01B 31/04; H01L 51/52

(52) U.S. Cl. CPC H01L 51/0021; H01L 51/5206; H01L 51/5234; H01L 51/56; C01B 31/0446; H01L 2251/558; C01P 2006/40; C01B 2204/04

(57) ABSTRACT

The present invention relates to a method of preparing an at least partially transparent and conductive layer (22) comprising graphene, the method comprising the steps of: (a) applying a dispersion comprising graphene oxide onto a substrate to form a layer comprising graphene oxide on the substrate, and (b) heating at least part of the layer obtained in step (a) by laser irradiation (34) at a laser output power of at least 0.036 W, thereby chemically reducing at least a part of the graphene oxide to graphene (33) and physically reducing the thickness of the layer by ablation. An advantage of the present invention is that it provides a simplified method of preparing a layer comprising graphene. The layer thus prepared has desirable transparency and conductivity.

### FIELD OF THE INVENTION

The invention relates to a method of preparing an at least partially transparent and conductive layer comprising graphene and a graphene layer obtainable by the method, as well as devices incorporating graphene layers obtainable by the method.

### BACKGROUND OF THE INVENTION

In recent years much time and effort has been put into the research area of graphene. Graphene is a two-dimensional carbon allotrope and has become well-known for its unique properties. Graphene is not only a very light material, but also very strong. Further it has an excellent ability to conduct both heat and electricity. Due to these properties graphene is expected to be useful in a wide range of applications, for example in the field of optical electronics, such as in organic light emitting diodes (OLEDs), displays and touch screens, in the field of ultrafiltration, or in energy storage, such as in batteries.

Different methods of producing graphene have been suggested. One such method is mechanical exfoliation, wherein graphene is prepared by dissecting graphite, layer by layer, until a monolayer of graphite, i.e. graphene, is achieved. However, mechanical exfoliation can today only produce very small quantities of graphene, typically surface areas limited to about 1 mm². An alternative method of producing graphene is chemical vapor deposition (CVD), in which gaseous reactants are deposited onto a substrate. Even though CVD may potentially produce high quality graphene in a large scale, the deposition step of this method is a relatively complicated and sensitive step, which is not part of a standard production technology.

Trusovas et al. “Reduction of graphite oxide to graphene with laser irradiation”, Carbon 52 (2013), p. 574-582, discloses a further approach to produce graphene. Trusovas et al. proposes to reduce graphene oxide, which is electrically and thermally insulating, to conductive graphene by the use of picosecond pulsed laser irradiation. However, the transparency and conductivity of the resulting layer are still unsatisfactory for many applications.

Hence, there is still a need in the art for improved methods of preparing an at least partially transparent and conductive layer comprising graphene.

### SUMMARY OF THE INVENTION

It is an object of the present invention to overcome this problem, and to provide a method of preparing an at least partially transparent and conductive layer comprising graphene.

According to a first aspect of the invention, this and other objects are achieved by a method of preparing an at least partially transparent and conductive layer comprising graphene, the method comprising the steps of:

(a) applying a dispersion comprising graphene oxide onto a substrate to form a layer comprising graphene oxide on the substrate, and
(b) heating at least part of the layer obtained in step (a) by laser irradiation at a laser output power of at least 0.036 W, thereby chemically reducing at least a part of the graphene oxide to graphene and physically reducing the thickness of the layer by ablation.

In some embodiments, the heating in step (b) is adapted to provide an energy density of less than 6.4 J/mm². In other embodiments, the heating in step (b) provides an energy density of less than 5 J/mm², such as less than 4 J/mm², or such as less than 3 J/mm². Hence, in a further aspect of the invention, there is provided a method of preparing an at least partially transparent and conductive layer comprising graphene, the method comprising the steps of:

(a) applying a dispersion comprising graphene oxide onto a substrate to form a layer comprising graphene oxide on the substrate, and
(b) heating at least part of the layer obtained in step (a) by laser irradiation at a laser output power of at least 0.036 W, thereby chemically reducing at least a part of the graphene oxide to graphene and physically reducing the thickness of the layer by ablation, wherein the heating in step (b) is adapted to provide an energy density of less than 6.4 J/mm².

The inventors have surprisingly found out that the thickness of the layer comprising graphene oxide is physically reduced by ablation, when at least a part of the layer comprising graphene oxide is laser irradiated at a laser output power of at least 0.036 W. Having been both chemically reduced (at least part of the graphene oxide has been converted to graphene) and physically reduced (the thickness of the layer has been decreased by ablation) the resulting layer of graphene has a desirable transparency and conductivity.

An advantage of using laser irradiation to effectuate the heating of step (b) is that it provides an effective way of rapidly heating the layer comprising graphene oxide. Another advantage of using laser irradiation is that the heating of step (b) may be targeted at certain areas of the layer comprising graphene oxide. Thereby selected portions of the layer comprising graphene oxide may be heat treated, and other portions may be left untreated or treated such that only chemical reduction, but not ablation, is achieved. In this way, the resulting layer comprising graphene oxide may be patterned and/or provided with layer thickness variations.

By the term “chemically reducing”, “chemically reduce” etc., is herein meant the chemical reduction in which at least a part of the graphene oxide, comprised in the layer comprising graphene oxide, is converted to graphene by chemical reaction.

By the term “physically reducing”, “physically reduce”, etc., is herein meant physical removal of matter from the layer such that the thickness of the layer comprising graphene oxide is decreased, at least locally. Thus at least a portion of the layer has a decreased layer thickness. Removal of matter is typically due to ablation.

By the term “ablation”, is herein meant the removal of matter from a surface, here removal of graphene oxide or graphene from the layer comprising graphene oxide or graphene. In the present invention ablation may occur when the layer comprising graphene oxide is subjected to heating as described above. It is believed that the removal of graphene oxide may be caused by the release of gas formed upon the rapid heating. More specifically, it is believed that the formation of gases in the form of CO_{N}, H₂O and O₂ during the reduction process leads to a strong gas pressure within the layer, for example between sheets of reduced graphene oxide (i.e. graphene). Due to this pressure, portions, e.g. flakes, of the layer may detach from the surface, hence ablating or eroding parts of the layer comprising graphene oxide. As a consequence, thinning of the layer is achieved.

Depending on the laser output power and beam speed used, and also depending on the layer thickness, the heat treatment may result in ablation to different extent. Low laser power and/or high beam speed may result in a weak ablating effect, referred to herein as “first stage ablation”. Operating at higher laser power and/or lower beam speed enables a stronger ablation of the graphene oxide layer. This stronger ablation effect is herein referred to as “second stage ablation”. During the first stage ablation, the laser is typically operating at a laser output power which is enough only to ablate a surface portion of the layer comprising graphene oxide and not deeper portions of the layer comprising graphene oxide, thereby leaving the deeper parts, which are closer to the substrate, unablated. Hence, a surface portion of the layer comprising graphene oxide can be removed (ablated) while sheets of graphene oxide beneath the removed portions are reduced to graphene, but not removed from the layer. The second stage ablation is achieved when the laser is operating at a laser output power which is sufficient to ablate a major portion of the graphene oxide, e.g. 90% or more of the layer thickness, while reducing sheets of graphene oxide closest to the substrate to graphene, thus leaving a thin layer of graphene.

Notably, both the first stage ablation and the second stage ablation are in themselves independent one-step processes. For the purpose of the present invention, the first stage ablation may be sufficient to produce the desired conductive and transparent layer of graphene, especially if the initial layer comprising graphene oxide is not too thick. However, in some embodiments, it may be desirable to utilize the second stage ablation to more strongly ablate a layer comprising graphene oxide in order to obtain a thin, at least partially conductive and transparent layer comprising graphene.

By the term “laser output power”, is herein meant the output power of which the laser is operating when irradiating the layer comprising graphene oxide.

By the term “beam speed”, is herein meant the speed at which the beam of a laser is moving across the layer comprising graphene oxide obtained in step (a) for chemically and/or physically ablating the same in the heating step (b).

By the term “absorbed laser power density”, is herein meant the laser power density of which is received and absorbed by the layer comprising graphene oxide when heating the same in step (b).

By the term “energy density”, is herein meant the energy density of which is received and absorbed by the layer comprising graphene oxide when heating the same in step (b).

By the term “exposure time”, is herein meant the time a particular region of the layer comprising graphene oxide is exposed to the laser beam in step (b).

An advantage of the method according to the present invention is that it is suitable for large scale synthesis of graphene starting from graphene oxide, e.g. in the form of a dispersion of graphene oxide flakes. The method further provides a simplified approach to providing the at least partially transparent and conductive layer comprising graphene by the use of standard production technologies for applying the layer comprising graphene oxide onto the substrate and for subsequently heating the layer comprising graphene oxide.

In some embodiments, the graphene oxide comprised in the dispersion in (a) may be uncharged or charge-neutral.

In some embodiments, the layer comprising graphene oxide is heated using a laser output power of at least 0.04 W, for example at least 0.045 W, at least 0.05 W, at least 0.058 W, at least 0.06 W, or at least 0.07 W.

In some embodiments, the heating in step (b) may be carried out at a beam speed of less than 0.1 m/s. For example, the heating in step (b) may be carried out at a beam speed of less than 0.08 m/s, or less than 0.06 m/s, or at a beam speed of less than 0.04 m/s. In some embodiments, the heating in step (b) is carried out at a beam speed of less than 0.005 m/s, or at a beam speed of about 0.001 m/s. The beam speed is suitably selected with regard to the laser output power, in order to achieve ablation. More specifically, the higher the beam speed, the higher laser output power is required in order to achieve ablation of the layer comprising graphene oxide when heating the same in step (b). Correspondingly, a lower beam speed allows for a lower laser output power. However, it may be beneficial to use a lower beam speed, while using a relatively high laser output power, in order to achieve an increased efficiency of the chemical and physical reduction process of step (b).

For example, the heating step (b) may utilize a laser output power of at least 0.036 W and a beam speed of 0.01 m/s or less, e.g. 0.005 m/s or less. Alternatively, the heating step (b) may utilize a laser output power of at least 0.05 W and a beam speed of 0.02 m/s or less, e.g. 0.01 m/s or less. It is envisaged that also a laser output power of less than 0.036 may achieve ablation when combined with very low beam speed, e.g. about 0.001 m/s (1 mm/s) or less.

In some embodiments, the layer is exposed to heating in step (b) of an exposure time of up to 15 ms. In other embodiments, the layer is exposed to heating in step (b) of an exposure time of less than 12 ms, such as less than 10 ms, or such as less than 8 ms. In other embodiments, the layer is exposed to heating in step (b) of an exposure time of less than 6 ms, such as less than 4 ms, or such as less than 2 ms. The exposure time is suitably selected with regard to the laser output power, and/or the absorbed laser power density, in order to achieve ablation. More specifically, the shorter the exposure time, the higher laser output power is generally required in order to achieve ablation of the layer comprising graphene oxide.

In some embodiments, the heating in step (b) is adapted to provide an absorbed laser power density of at least 400 W/mm². For example, the heating in step (b) may be adapted to provide an absorbed laser power density of at least 500 W/mm², such as at least 600 W/mm², or at least 700 W/mm². In some embodiments, the heating in step (b) is adapted to provide an absorbed laser power density of at least 800 W/mm².

In some embodiments, the heating in step (b) is adapted to provide an energy density of less than 6.4 J/mm². In other embodiments, the heating in step (b) provides an energy density of less than 5 J/mm², such as less than 4 J/mm², or such as less than 3 J/mm².

In some embodiments, selected portions of the layer comprising graphene oxide may be subjected to heating whereas other portions of the layer may be left untreated. Different regions of the layer may be heated, simultaneously or sequentially, such that more than one single portion of the layer is subjected to the heat treatment. Hence, the heating may result in a layer comprising one or more portions or zones of graphene. Optionally some portion(s) of the layer comprising graphene oxide may be left untreated (not heated).

In some embodiments, the thickness of the layer comprising graphene oxide obtained in step (a) may be in the range of from 5 nm to 100 μm, for example from 100 nm to 50 μm. In some embodiments, the thickness of the layer obtained in step (a) may be at least 50 nm, such as at least 100 nm, or at least 200 nm. In other embodiments, the thickness of the layer obtained in step (a) may be at least 300 nm, such as at least 400 nm, or such as at least 500 nm, or at least 1 μm, or at least 2 μm, or at least 5 μm, or at least 10 μm, or at least 20 μm. An advantage of starting with a relatively thick layer is that the layer absorbs more heat which enables or at least facilitates ablation. Therefore, a layer comprising graphene oxide having a layer thickness of at least 100 nm may be beneficial, although also smaller layer thickness may yield acceptable results.

The layer comprising graphene resulting from step (b), or at least a region thereof, may have a thickness in the range of from 1 to 10 nm, e.g. from 1 to 5 nm. The thickness of the layer comprising graphene obtained after heating is typically smaller than the thickness of the layer comprising graphene oxide prior to heating. A reduced thickness may contribute to an increased transparency of the layer comprising graphene.

In some embodiments, the graphene oxide comprised in the dispersion used in step (a) is present in the form of graphene oxide flakes. An advantage of using graphene oxide flakes is that they are relatively inexpensive to produce and can be made in large quantities by e.g. mechanical exfoliation. A further advantage of using a dispersion comprising graphene oxide flakes is that it can be applied onto a substrate using well-known production technologies.

In some embodiments, the substrate may be uncharged prior to the application of the dispersion in step (a).

In some embodiments, step (a) is effectuated by a wet-chemical deposition method. In embodiments of the invention, the wet-chemical deposition method may be selected from spin coating, dip coating, spraying, ink jet printing, roll-to-roll (R2R) printing, screen printing, blade coating and drop casting. An advantage of using a wet-chemical deposition method which is part of standard production technology is that the method is reliable and relatively easy to perform.

In a second aspect, the invention provides a graphene layer obtainable by the method according to the present invention. The previously stated advantages of the method also apply to the graphene layer obtainable by this method. Such a graphene layer may be obtained according to specific embodiments and examples as disclosed in the method aspect. A further advantage of the graphene layer is that it may be flexible and hence may be used in flexible devices. The graphene layer, which only comprises carbon, may replace relatively scarce and potentially harmful materials.

In further aspects, the invention provides an optoelectronic device and a large area electronic device, respectively, comprising a conductive graphene layer obtainable by the method described herein.

It is noted that the invention relates to all possible combinations of features recited in the claims.

### BRIEF DESCRIPTION OF THE DRAWINGS

This and other aspects of the present invention will now be described in more detail, with reference to the appended drawings showing embodiment(s) of the invention.

FIG. 1 shows a flow chart depicting one example of a method of preparing an at least partially transparent and conductive layer comprising graphene according to the present invention.

FIG. 2 shows a cross sectional side view of a layer comprising graphene oxide applied onto a substrate according to embodiments of the invention.

FIG. 3 shows a cross sectional side view of a layer comprising graphene oxide on a substrate which is subjected to heating by laser irradiation according to embodiments of the invention.

FIG. 4 shows a cross sectional side view of a layer comprising graphene on a substrate which has been chemically and physically reduced according to embodiments of the invention.

FIG. 5 shows a cross sectional side view of a patterned layer comprising parts which have been chemically and physically reduced, and parts which have only been chemically reduced, according to embodiments of the invention.

FIG. 6 shows a top view of a patterned layer comprising regions which have been chemically and physically reduced, and regions which have only been chemically reduced, according to embodiments of the invention.

FIG. 7 is a graph showing the transmission and the reflectance, as well as the absorption, of a layer comprising graphene oxide and a pattern comprising graphene according to embodiments of the invention.

FIG. 8 is a graph plotting laser beam speed versus absorbed laser power density, illustrating parameters which result in reduction and ablation.

FIG. 9 is a graph plotting laser beam speed versus laser output power, illustrating parameters which result in reduction and ablation.

FIG. 10 is a graph plotting exposure time versus absorbed power density, illustrating parameters which result in reduction and ablation.

FIG. 11 shows a side view of an optoelectronic device comprising a graphene layer produced according to embodiments of the invention.

### DETAILED DESCRIPTION

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled person. Like reference numerals in the drawings refer to like elements throughout.

The present inventors have found out that by subjecting a layer comprising graphene oxide to rapid and strong heating, in particular heating by laser irradiation at a laser output power of at least 0.036 W, an at least partially transparent and conductive layer comprising graphene is achieved, wherein the reduced thickness is achieved by ablation.

In examples of the invention, the substrate may be of any suitable material, for example a plastic, glass, ceramic or metallic material. Optionally, the substrate may be transparent. It may be advantageous to use a substrate of glass, or of plastic. The use of glass or plastic, which may have low thermal conductivity, may lead to a controlled ablation of the layer comprising graphene oxide. Alternatively, a substrate of metal may be used. The heating rate provided by the laser irradiation may be suitably adapted in view of the substrate material, considering that a metal substrate may absorb more heat than a substrate of glass or plastic. For example, a higher laser output power may be useful when using a substrate of metal compared to when using a substrate of glass, in order to suit the different thermal properties of the substrate materials.

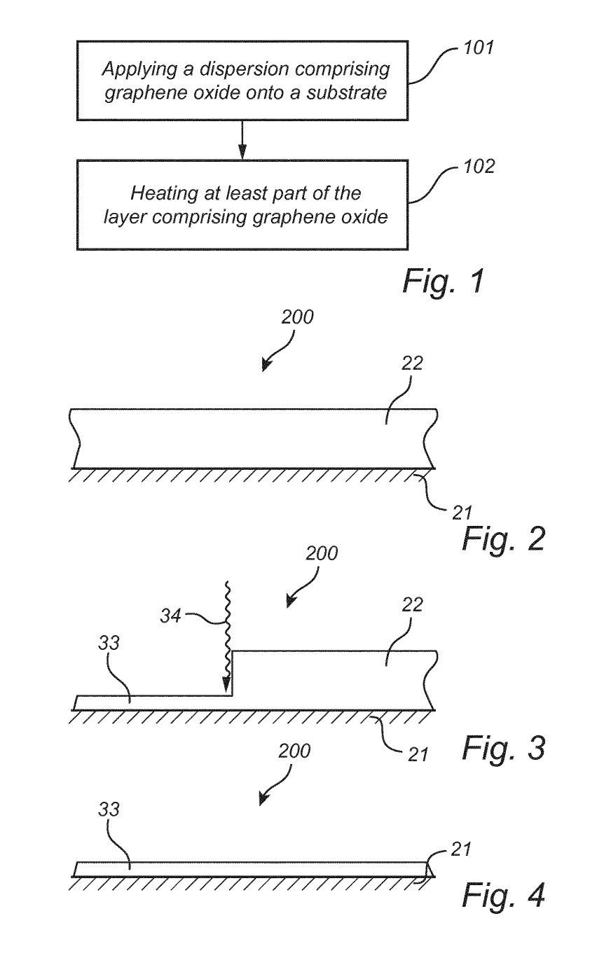

FIG. 1 shows a flow chart of a method 100 of preparing an at least partially transparent and conductive layer comprising graphene according to the present invention. In a first step 101, a dispersion comprising graphene oxide is applied onto a substrate to form a layer comprising graphene oxide on the substrate. Thereafter the layer comprising graphene oxide is, in a second step 102, heated by laser irradiation, at a laser output power of at least 0.036 W. Thereby at least a part of the graphene oxide is chemically reduced to graphene and the thickness of the layer is physically reduced by ablation.

The graphene oxide used in step 101 can be dispersed in a solution, such as an aqueous solution. Such a dispersion thus comprises a carrier phase, e.g. water, and graphene oxide. The dispersion may have a concentration of graphene oxide of less than 30% by weight of the carrier phase (w/w), such as less than 20% by weight of the carrier phase (w/w). For example, as the dispersion may have a content of graphene oxide about 0.4% by weight of the carrier phase (w/w).

The dispersion may be applied onto the substrate by a wet-chemical deposition method, such as a method selected from spin coating, dip coating, spraying, ink jet printing, roll-to-roll printing, screen printing, blade coating and drop casting. A further wet-chemical deposition method that may be used is (di)-electrophoresis. The applied dispersion may thereafter be allowed to dry, so as to form the layer comprising graphene oxide on the substrate. The applied dispersion may, in an example, be allowed to air-dry. In another example the applied dispersion may be subjected to heating at a low temperature, so as to speed up the drying process. The drying temperature may be low so that the drying step does not result in any substantial reduction of the graphene oxide.

The viscosity and concentration of the dispersion can be adapted to suit the deposition method used for applying the dispersion onto the substrate, and/or any after-treatment such as drying.

After deposition and optionally drying, the thickness of the layer comprising graphene oxide may be in the range of from 5 nm to 100 μm, for example in the range of from 100 nm to 50 μm. In some embodiments, the thickness of the layer comprising graphene oxide may be at least 50 nm, such as at least 100 nm, or at least 200 nm. In other embodiments, the thickness of the layer comprising graphene oxide may be at least 300 nm, such as at least 400 nm, or such as at least 500 nm. In yet other embodiments, the thickness of the layer comprising graphene oxide may be at least 1 μm, at least 2 μm, at least 5 μm, or at least 10 μm. From a manufacturing/processing perspective, it may be advantageous to use a layer comprising graphene oxide having a thickness of less than 100 μm, such as less than 30 μm. The thicker the layer comprising graphene oxide is, the more light absorbing it may be. A thicker layer may require a longer exposure time to result in ablations of most of the layer to arrive at the desired small thickness graphene layer.

The heating step 102 is effectuated by laser irradiation, at a laser output power of at least 0.036 W. In embodiments of the invention, the layer comprising graphene oxide is heated using a laser output power of at least 0.04 W, for example at least 0.045 W, at least 0.05 W, at least 0.06 W, or at least 0.07 W. The laser irradiation may be carried out by moving a laser beam over the region(s) of the layer to be treated in the plane of the layer comprising graphene oxide at a beam speed of less than 0.1 m/s. For example, the heating in step (b) may be carried out at a beam speed of 0.08 m/s or less, such as 0.06 m/s or less, or 0.04 m/s or less, or 0.03 m/s or less. In some embodiments, the heating in step (b) may be carried out at a beam speed of less than 0.02 m/s, e.g. about 0.01 m/s, or less.

In embodiments of the invention, the entire layer comprising graphene oxide may be subjected to heating. Thereby, the entire layer comprising graphene oxide may be reduced to produce a layer of graphene lacking regions or zones of graphene oxide. Alternatively, certain regions(s) of the layer comprising graphene oxide may be selectively heat treated, such as to create thin, reduced regions comprising graphene. Untreated (unheated) regions may remain as regions comprising graphene oxide having the same thickness as the layer which was originally applied (optionally after drying). Optionally, after the first heating of the selected portion(s), the entire layer, including both treated and untreated regions, may be subjected to a second heating, e.g. in order to decrease the sheet resistance of the layer. In the second heating, at least the previously untreated region(s) of graphene oxide, but optionally the entire layer, may be heated, however using a lower energy dose which is only enough to chemically reduce the graphene oxide of the previously untreated region(s) to graphene, without physically reducing the layer thickness. In this way, thin ablated portions comprising graphene as well as thicker, non-ablated portions comprising graphene are obtained.

The heating step 101 may be adapted to provide an energy density of less than 6.4 J/mm², such as less than 5 J/mm², or such as less than 4 J/mm². The heating of the layer comprising graphene oxide may be adapted to provide an absorbed laser power density of at least 400 W/mm², such as at least 500 W/mm², or such as at least 600 W/mm². Such sudden heating achieves ablation or erosion of the layer, as explained above, thereby decreasing the layer thickness.

Table 1 below presents corresponding values of beam speed and laser output power at which of first stage or second stage ablation, respectively, may be achieved. In general, when the beam speed is increased, an increased laser output power may be required in order to achieve the same extent of ablation.

TABLE 1
Examples of beam speed and laser output
power useful for providing ablation

| Maximum beam speed | Laser output power [W] | |
|---|---|---|
| [m/s] | First stage ablation | Second stage ablation |
| <0.01 | ≧0.036 | ≧0.04 |
| 0.01 | ≧0.045 | ≧0.055 |
| 0.02 | ≧0.05 | ≧0.06 |
| 0.03 | ≧0.056 | ≧0.062 |
| 0.04 | ≧0.058 | ≧0.064 |
| 0.06 | ≧0.06 | ≧0.066 |
| 0.08 | >0.06 | ≧0.068 |
| 0.1 | >0.06 | ≧0.07 |

As demonstrated in the example below, satisfactory second stage ablation may be achieved using lower beam speed than suggested above. For example, the invention may advantageously use a laser beam speed in the range of from less than 0.001 m/s (1 mm/s) up to 0.01 m/s (10 mm/s), e.g. from 0.001 m/s (1 mm/s) to 0.005 m/s (5 mm/s), and typically about 1 mm/s. Beam speeds in these ranges are advantageously combined with laser output power of less than 0.06 W, less than 0.05 W or even 0.04 W or less.

The laser irradiation wavelength may be in the range of from 200 nm to 10 μm, especially in the range of from 200 nm to 700 nm. Specific examples of useful laser wavelengths for heating the layer comprising graphene oxide include wavelengths of 405 nm, 532 nm, 663 nm, 680 nm, 788 nm, 1064 nm and 1000 nm. The laser may be selected with due regard to the absorption properties of the substrate material, for example to avoid undesired absorption by the substrate.

In some embodiments, the layer comprising graphene oxide may be heated at a rate of at least 100° C./second. According to other embodiments the layer comprising graphene oxide may be heated at a rate of at least 200° C./second, or such as at a rate of at least 300° C./second.

The layer comprising graphene resulting from step (b) may have a thickness in the range of from 1 to 10 nm, such as in the range of from 1 to 8 nm, and preferably 1 to 5 nm. A reduced thickness may contribute to an increased transparency of the layer comprising graphene.

The graphene oxide comprised in the dispersion used in step a, may be present in the form of graphene oxide flakes. FIGS. 2-4 illustrate a layer arrangement at the different stages of the method described above.

FIG. 2 shows a cross sectional side view of an arrangement 200 comprising a layer 22 comprising graphene oxide, which has been applied onto a substrate 21. The graphene oxide layer 22 has not yet been subjected to the heat treatment according to the invention.

FIG. 3 shows a cross sectional side view of the arrangement 200 during the heating step b of the method described above. The layer 22 comprising graphene oxide is subjected to heat treatment by local irradiation with a laser beam 34 effecting heating at a laser output power of at least 0.036 W. Thereby at least a part of the graphene oxide is chemically reduced to graphene, thus forming a layer 33 of graphene. FIG. 3 also shows that the thickness of the layer comprising graphene oxide is physically reduced, i.e. decreased. Through this chemical and physical reduction, the layer 33 comprising graphene has a decreased thickness compared to the layer 22 comprising graphene oxide.

FIG. 4 shows a cross sectional side view of the arrangement 200 after the heating (i.e. after step b). The arrangement 200 thus comprises a layer 33 which has been both chemically reduced to graphene and partially ablated.

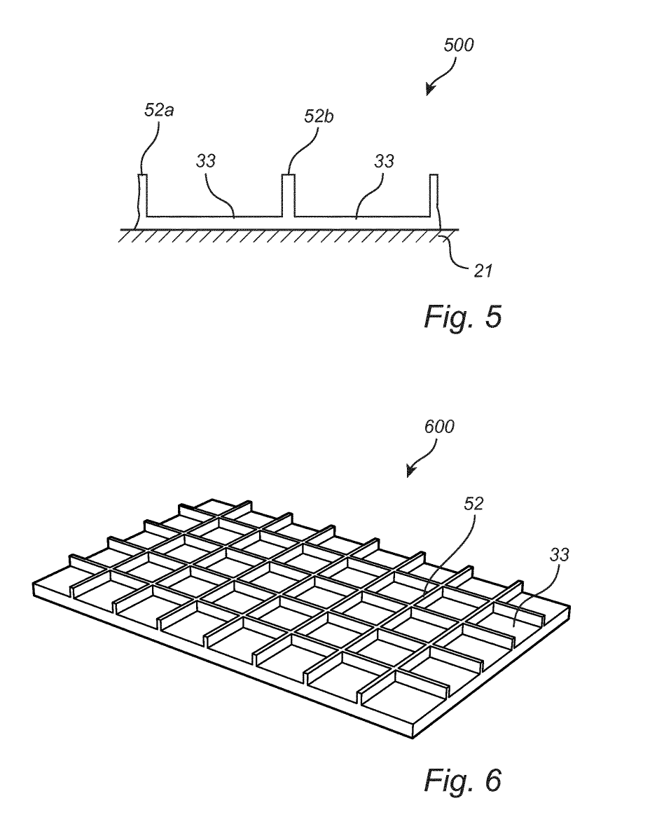

FIG. 5 shows a cross sectional side view of an arrangement 500 comprising a layer 33 comprising graphene including portions 52a, 52b also comprising graphene. The arrangement 500 may be produced by as described above, by first applying a layer comprising graphene oxide onto the substrate 21 and subsequently subjecting the layer to heating in two steps: In the first heating step, selected portions of the applied layer comprising graphene oxide is subjected to heating as described above, to create the heat treated ablated portions comprising graphene 33, having a decreased thickness, and leaving the remaining untreated non-ablated portions comprising graphene oxide. In the second heating step, the entire layer, including portions of graphene oxide as well as portions of graphene is subjected to heating as described above sufficient for converting graphene oxide to graphene but insufficient for ablation, resulting in portions 52a, 52b comprising graphene. The portions 52a, 52b have about the same thickness as compared to the layer comprising graphene oxide originally applied onto the substrate (after any drying of the applied dispersion).

The layer comprising graphene produced by the method according to embodiments of the invention may have a sheet resistivity in the range of from 10 Ω/sq to 100 k Ω/sq to, for example from 30 Ω/sq to 10 kΩ/sq. For instance, the sheet resistivity may be about 30 Ω/sq, or even lower.

The layer comprising graphene produced by the method according to embodiments of the invention may as a whole have a transparency in the range of from 50% to 90%, such as within the range of from 60% to 90%, or such as within the range of from 70% to 90%. However, it is envisaged that certain portions of the layer may have a transparency lower than 50% and may even be completely absorbing (i.e. 0% transparency). The degree of transparency may depend on the resulting thickness of the layer comprising graphene, i.e. a thinner layer may be more transparent compared to a thicker layer. The degree of transparency may further depend on whether the layer has been patterned or not.

FIG. 6 shows a top view of an arrangement 600 comprising a patterned layer comprising graphene 33 and portions 52a, 52b comprising graphene, according to the description of FIG. 5.

The method described herein may be used for preparing graphene layers to be used as an electric conductor in electronic devices or optoelectronic devices (for example OLEDs or displays). In particular, a graphene layer produced as described above is useful for large surface area applications, such as large area electronics and large area displays. In the case of OLEDs and displays, the method described above can advantageously be used for producing a thin, conductive and, if desired, acceptably transparent layer of graphene which may function as an electrode layer (cathode or anode). In the case of large area electronics, the method described herein may be used for producing a patterned and optionally transparent layer of graphene which may serve as the circuitry. In such embodiments, a conductive pattern of graphene regions may be formed, by laser irradiation, in a layer of non-conductive graphene oxide, leaving a major portion of the layer untreated and thus still formed of graphene oxide.

In the present context, “large area” means a surface area covered with graphene having an extension in at least one direction of 5 mm or more, or 1 cm or more. For example, a conductive path of graphene having a path length of at least 5 mm, or at least 1 cm, and a path width of at least 10 μm is considered a large area. As another example of a “large area” is a quadratic surface region covered with graphene having an area of 1 cm² or more.

FIG. 11 shows an example of an optoelectronic device, here an OLED comprising a graphene layer produced by the method described above. The OLED 10 comprises, in this order, a substrate 11, a first electrode layer 12 comprising graphene acting, active layer(s) 13 and a second electrode layer 14. Upon application of a voltage between the first and second electrode layers 12, 14, light is generated in the active layer(s) 13 and may be emitted via the first electrode layer 12 and the substrate 11 and/or via the second electrode 14.

The first electrode layer 12 comprising graphene may be provided as described above, by applying a dispersion comprising graphene oxide onto the substrate 11, followed by laser irradiation to reduce the graphene oxide to graphene and to decrease the layer thickness. Hence, the substrate 11 may be as described above. The substrate 11 may be transparent in order to allow light emission via the first electrode layer and the substrate. The first layer 12 comprising graphene may serve as the anode or the cathode. The electrode layer 12 may be a continuous layer having uniform layer thickness. Optionally, the layer 12 may be patterned to comprise first regions of graphene having a small layer thickness, corresponding to regions 33 of FIG. 3, and second regions of graphene of larger thickness, corresponding to regions 52 of FIG. 6.

After formation of the first electrode layer 12 on the substrate 11 by deposition of graphene oxide and laser irradiation to form graphene and reduce the layer thickness, the active layer(s) 13 and the second electrode layer 14 may be deposited onto the first electrode layer 12 using conventional methods.

The active layer(s) 13 of the device is thus arranged on the first electrode layer 12 and may have a conventional structure, comprising at least one light emitting layer, where recombination of charges takes place and light is generated. However, optionally the layer(s) 13 may also comprise one or more charge injection and/or charge transporting layers arranged between the light emitting layer and at least one of the first electrode layer 12 and the second electrode layer 14.

Finally, the second electrode layer 14 is arranged on the active layer(s) 13 on the opposite side thereof in relation to the first electrode 12. The second electrode layer may serve either as the anode or the cathode. The second electrode layer 14 may be a conventional electrode used in OLEDs, formed of a conductive material such as ITO or a metal. Optionally the second electrode 14 may be transparent, to allow light emission via the electrode layer 14. The OLED 10 may further comprise conventional components such as electrical and optical components, protective layers, etc.

### EXAMPLES

The inventors investigated the transmission and the sheet resistance, as well as the reflectance and absorbance of an at least partially transparent and conductive layer comprising graphene prepared according to embodiments of the inventive method. The inventors further investigated exemplary values of beam speed, absorbed laser power density, laser output power, exposure time and energy density, sufficient for physically reducing the thickness of the layer comprising graphene oxide by ablation.

### Example 1

### Preparation of Uniform Graphene Layer

Graphene oxide flakes were dispersed in water by adding 4 mg of graphene oxide flakes per g water to form an aqueous suspension. The suspension thus had a content of graphene oxide flakes of 0.4% by weight of the carrier phase (w/w). The graphene oxide flakes were obtained from the distributor Graphene.

The dispersion comprising graphene oxide was in a first example applied onto a substrate of glass to form a layer comprising graphene oxide on the substrate. The layer comprising graphene oxide had a thickness of about 20 to 30 μm. The layer comprising graphene oxide was applied onto the substrate by a drop casting method. The layer comprising graphene oxide was thereafter allowed to dry. After drying, the layer was subjected to laser treatment by a continuous wave (CW) laser (Nichia solid state laser diode 405 nm, 110 mW) set to a power of 58 mW and focused on a 10 μm large spot on the layer comprising graphene oxide. The laser beam was allowed to move in the x-y plane of the layer comprising graphene oxide at a speed of 5 mm/s, without a wobble frequency, by a galvanoscanner with a focus plane correction. The scanning laser beam from the CW laser effectuated heating in the entire layer comprising graphene oxide. Thereby at least a part of the graphene oxide, comprised in the layer was chemically reduced to graphene. Further, the thickness of the layer comprising graphene oxide was physically reduced by ablation. After the laser treatment, a resulting layer comprising graphene having a reduced thickness of about 7 to 8 nm was achieved. The resulting layer comprising graphene on glass had a sheet resistance of 2.3 kΩ/sq, a transparency of 55% at 600 nm and an absorption of 15% at 600 nm.

### Example 2

### Preparation of Patterned Graphene Layer

In a second example, a patterned layer comprising graphene oxide was prepared. A dispersion comprising graphene oxide was applied onto a substrate of glass to form a layer comprising graphene oxide on the substrate as described for the first example above. The layer comprising graphene oxide had a thickness of about 20 to 30 μm. After drying, selected portions of the layer comprising graphene oxide were subjected to laser treatment, by irradiation with the laser beam from the CW laser used in Example 1. Hence, laser irradiation was used to effectuate heating in said selected portions, while other parts of the layer were left untreated at this stage. The irradiated portions of the layer formed a pattern of squares of 0.5×0.5 mm. In these squares at least a part of the graphene oxide was chemically reduced to graphene, and the layer thickness was physically reduced by ablation. This laser treatment thus resulted in a pattern of untreated portions of graphene oxide having a width of about 50 μm and a layer thickness of 20 μm disposed between heat treated portions of graphene having a thickness of about 7 to 8 nm. The thus patterned layer had a sheet resistance of 3.5 k Ω/sq. This patterned layer had a higher value of sheet resistance compared to the layer comprising graphene of the first example, since the untreated portions at this stage had not yet been reduced and thus still comprised graphene oxide.

The layer was next subjected to a second laser treatment in which the entire layer was irradiated. The laser had a power of 50 mW and the laser beam was allowed to move in the x-y plane of the layer comprising graphene oxide at a speed of 100 mm/s. The heating effectuated by the laser beam resulted in reduction of graphene oxide comprised in the previously untreated portions to graphene, and leaving the previously heat treated graphene portions unaltered. The conditions were such that no ablation occurred and the layer thickness was thus substantially maintained. The resulting patterned and reduced layer comprising graphene had a resistance of 0.9 kΩ/sq.

A wobble frequency was not applied in neither of the first and second examples, since other examples (not shown) have demonstrated that the resistivity of the resulting layer comprising graphene was higher, such as a resistivity of 9 kΩ/sq, when the wobble frequency was applied. However the wobble frequency has been shown to speed up the writing time of the laser beam.

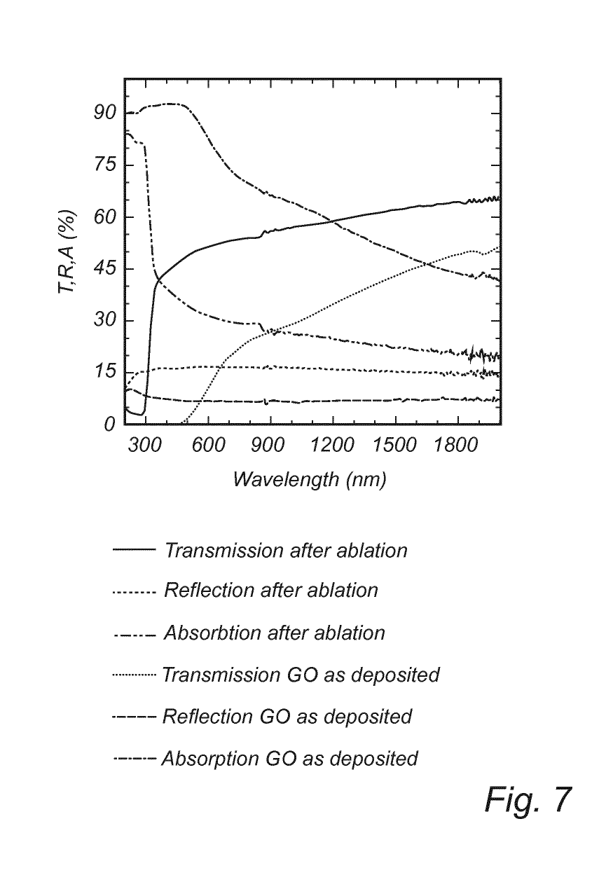

FIG. 7 is a graph illustrating the transmission and the reflectance, as well as the calculated absorption, of the layer comprising graphene oxide obtained in step (a) as well as of the patterned layer comprising graphene prepared according to the second example (as measured after the second laser treatment).

As can be seen in FIG. 7, the patterned layer comprising graphene on a glass substrate shows a transmission curve which has a steep increase at wavelengths in the range of from 300 to about 400 nm, which may be due to the use of the glass substrate, where the transmission reaches a value of about 45% transmission, i.e. about 45% of the light having a wavelength of about 400 nm passes through the layer comprising graphene and its substrate. As the wavelengths increases, the transmission also increases and at about 600 nm, the transmission is 55%. Further, as the wavelength increases, the transmission has a linear increase up to about 65% at a wavelength of 2000 nm. In the same wavelength range, the transmission curve of the layer comprising graphene oxide, prior to heat treatment, shows lower values of transmission than of the patterned layer after ablation.

The reflection of the patterned layer comprising graphene was about 15%, i.e. the amount of light, which is neither absorbed by the layer or its substrate nor let through it, at wavelengths in the range of from 250 to 2000 nm. In the same wavelength range, the reflection curve of the layer comprising graphene oxide, prior to heat treatment, shows a lower value of about 7.5% reflection. The absorbance of the patterned layer comprising graphene and of the layer comprising graphene oxide can be calculated from the values of transmittance and reflection, respectively.

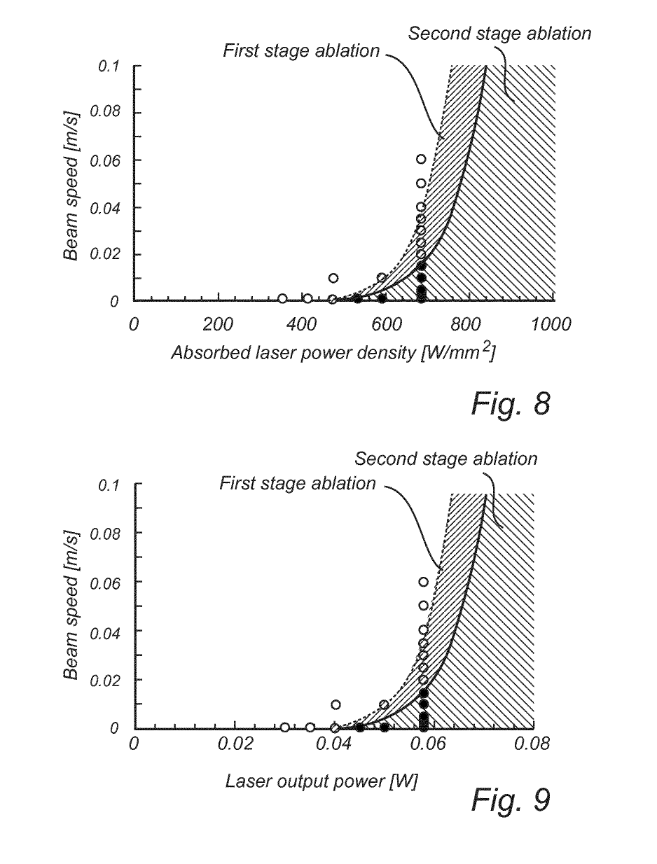

In the FIGS. 8 to 10, which will be described in more detail below, the dots in the respective graphs represent measured values. A solid black dot represents second stage ablation, a striped dot represents first stage ablation, and a solid white dot represents a measured value of when no ablation has occurred.

FIG. 8 is a graph showing beam speed versus absorbed laser power density, a curve fitted to data values obtained for a 20 μm graphene oxide layer on a glass substrate. The dashed curve delimits the conditions at which first stage ablation occurs, and the solid curve delimits conditions at which second stage ablation or complete ablation occurs. Thus, the area to the left of the dashed curve represents conditions at which no ablation occurs. The area in-between the dashed curve and the solid curve represents conditions at which first stage ablation occurs. The area to the right of the solid curve represents conditions in which second stage ablation occurs. Table 2 shows data values for first stage and second stage ablation, respectively, extracted from the respective graphs of FIG. 8. First stage ablation starts at an absorbed laser power density of about 410 W/mm² and as the beam speed increases to 0.1 m/s, the absorbed laser power density required for at least first stage ablation increases to about 700 W/mm². The second stage ablation occurs with an absorbed laser power density of about 480 W/mm² and as the beam speed increases to 0.1 m/s, the absorbed laser power density increases to about 820 W/mm² (see Table 2, FIG. 8).

TABLE 2
Exemplary beam speed and absorbed laser power density useful
for first stage and second stage ablation, respectively.

| | |
|---|---|
| Beam speed | Absorbed laser power density [W/mm²] |

| [m/s] | First stage ablation | Second stage ablation |
|---|---|---|
| <0.01 | about 450 | about 500 |
| 0.01 | about 600 | about 680 |
| 0.02 | about 640 | about 750 |
| 0.04 | about 700 | about 800 |
| 0.06 | about 750 | about 800 |
| 0.08 | about 750 | about 850 |
| 0.1 | about 750 | about 850 |

FIG. 9 is a graph showing beam speed versus laser output power fitted to data values obtained for a 20 μm graphene oxide layer on a glass substrate. The dashed curve delimits the conditions at which first stage ablation occurs, and the solid curve delimits conditions at which second stage ablation or complete ablation occurs. Hence, similarly to FIG. 8, the area to the left of the dashed curve represents conditions at which no ablation occurs, the area in-between the dashed curve and the solid curve represents conditions at which first stage ablation occurs, and the area to the right of the solid curve represents conditions in which second stage ablation occurs. Table 3 shows values resulting in first stage and second stage ablation, respectively, extracted from the respective graphs of FIG. 9. First stage ablation starts at a laser output power of about 0.036 W and as the beam speed increases to 0.1 m/s, the laser output power increases to about 0.06 W. The second stage ablation occurs with laser output power of about 0.036 W and as the beam speed increases to 0.1 m/s, the laser output power increases to about 0.07 W (see Table 3, FIG. 9).

TABLE 3
Examples of beam speed and laser output power useful for achieving
first stage ablation or second stage ablation, respectively.

| | |
|---|---|
| Beam speed | Laser output power [W] |

| [m/s] | First stage ablation | Second stage ablation |
|---|---|---|
| <0.01 | about 0.036 | about 0.04 |
| 0.01 | about 0.05 | about 0.06 |
| 0.02 | about 0.06 | >0.06 |
| 0.03 | about 0.06 | >0.065 |
| 0.04 | >0.06 | >0.07 |
| 0.06 | >0.06 | >0.07 |
| 0.08 | >0.06 | >0.07 |
| 0.1 | >0.06 | >0.07 |

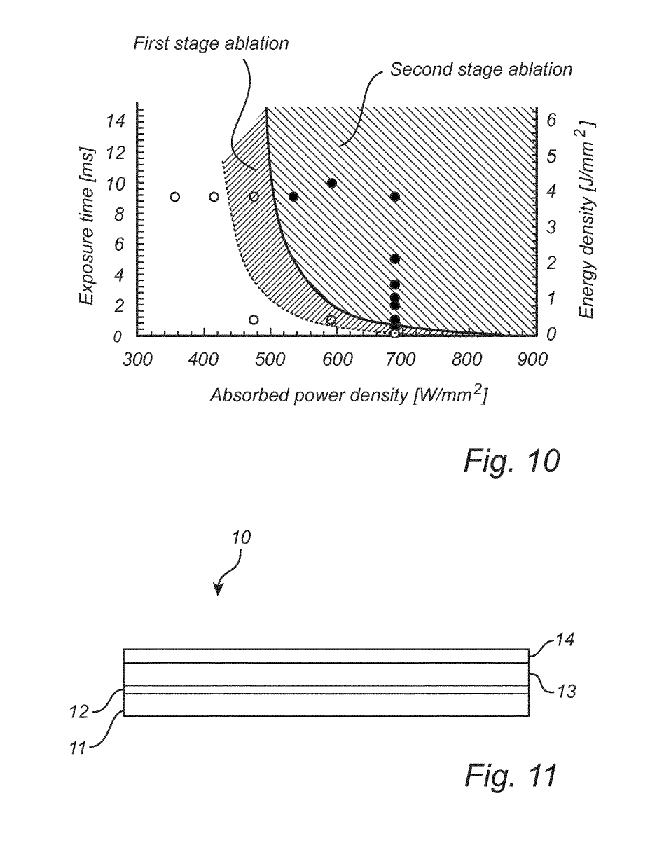

FIG. 10 is a graph showing exposure time to heat treatment versus absorbed laser power density, and versus energy density, fitted to data values obtained for a 20 μm graphene oxide layer on a glass substrate. The dashed curve delimits the conditions at which first stage ablation occurs, and the solid curve delimits conditions at which second stage ablation or complete ablation occurs. Hence, similarly to FIG. 8, the area to the left of the dashed curve represents conditions at which no ablation occurs, the area in-between the dashed curve and the solid curve represents conditions at which first stage ablation occurs, and the area to the right of the solid curve represents conditions in which second stage ablation occurs. Table 4 shows data values for first stage and second stage ablation, respectively, based on the respective graphs of FIG. 11. The layer comprising graphene was patterned with a 0.5×0.5 mm large grid according to Example 2. First stage ablation starts with an absorbed laser power density of about 700 W/mm² and as the exposure time to the heat treatment increases to 10 ms, and as the energy density increases to 4.2 J/mm², the absorbed laser power density decreases to about 430 W/mm². The second stage ablation occurs with an absorbed laser power density of about 800 W/mm² and as the exposure time to the heat treatment increases to 10 ms, and as the energy density increases to 4.2 J/mm², the absorbed laser power density decreases to about 500 W/mm² (see Table 11, FIG. 11).

TABLE 4
Exemplary exposure time to heat treatment and absorbed
laser power density, in relation to energy density for
first stage and second stage ablation, respectively.

| Exposure | Energy density | Absorbed laser power density [W/mm²] | |
|---|---|---|---|
| time [ms] | [J/mm²] | First stage ablation | Second stage ablation |
| 0 | about 0 | about 700 | about 800 |
| 1 | about 0.5 | about 600 | about 680 |
| 2 | about 0.8 | about 510 | about 520 |
| 4 | about 1.8 | about 480 | about 570 |
| 6 | about 2.6 | about 470 | about 540 |
| 8 | about 3.4 | about 460 | about 530 |
| 9 | about 3.8 | about 450 | about 530 |
| 10 | about 4.2 | about 440 | about 530 |

It should be noted that the values for exposure time and absorbed power density, as well as beam speed and laser output density required for ablation of graphene oxide or graphene may vary with the thickness of the graphene oxide layer and the type of substrate used. Hence values lower or higher than those presented in FIGS. 8-11 and Tables 1-4 may still provide ablation and may thus be within the scope of the invention.

The person skilled in the art realizes that the present invention by no means is limited to the preferred embodiments described above. On the contrary, many modifications and variations are possible within the scope of the appended claims. For example, the thickness of the layer comprising graphene oxide applied in step (a) in the inventive method may be adjusted. Moreover, the laser apparatus settings may be adapted to optimally fit a desired application with regard to, for example, laser power density and the writing time of the laser beam, as well as the optical and thermal properties of the substrate.

Additionally, variations to the disclosed embodiments can be understood and effectuated by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage. For the avoidance of doubt, the present application is directed to the subject-matter described in the following numbered paragraphs:

1. A method of preparing an at least partially transparent and conductive layer comprising graphene, the method comprising the steps of:

(a) applying a dispersion comprising graphene oxide onto a substrate to form a layer comprising graphene oxide on the substrate, and

(b) heating at least part of the layer obtained in step (a) by laser irradiation at a laser output power of at least 0.036 W, thereby chemically reducing at least a part of the graphene oxide to graphene and physically reducing the thickness of the layer by ablation.

2. The method according to paragraph 1, wherein the layer comprising graphene oxide is heated by laser irradiation at a laser output power of at least 0.04 W.
3. The method according to paragraph 1, wherein the layer comprising graphene oxide is heated by laser irradiation at a laser output power of at least 0.058 W.
4. The method according to paragraph 1, wherein the heating in step (b) is carried out at a beam speed 0.1 m/s or less.
5. The method according to paragraph 1, wherein the heating in step (b) is carried out at a beam speed of 0.04 m/s or less.
6. The method according to paragraph 1, wherein the heating in step (b) provides a laser output power of at least 0.036 W and is carried out at a beam speed of 0.01 m/s or less.
7. The method according to paragraph 1, wherein the heating in step (b) provides a laser output power of at least 0.05 W and is carried out at a beam speed of 0.02 m/s or less.
8. The method according to paragraph 1, wherein the layer is exposed to heating in step (b) of an exposure time of less than 15 ms.
9. The method according to paragraph 1, wherein the thickness of the layer obtained in step (a) is in the range of from 5 nm to 100 μm.
10. The method according to paragraph 1, wherein the thickness of the layer obtained in step (a) is at least 100 nm.
11. The method according to paragraph 1, wherein the thickness of the layer obtained in step (a) is at least 1 μm.
12. The method according to paragraph 1, wherein at least a region of the layer comprising graphene resulting from step (b) has a thickness in the range of from 1 to 10 nm.
13. A graphene layer obtainable by the method according to any one of the paragraphs 1 to 12.
14. An optoelectronic device comprising a conductive graphene layer obtainable by the method according to any one of the paragraphs 1 to 12.
15. An electronic device comprising a conductive graphene layer obtainable by the method according to any one of the paragraphs 1 to 12.

1. A method of preparing an at least partially transparent and conductive layer comprising graphene, the method comprising the steps of:
(a) applying a dispersion comprising graphene oxide onto a substrate to form a layer comprising graphene oxide on the substrate, wherein the thickness of the layer obtained in step (a) is at least 10 μm and
(b) heating at least part of the layer obtained in step (a) by laser irradiation at a laser output power of at least 0.036 W, thereby chemically reducing at least a part of the graphene oxide to graphene and physically reducing the thickness of the layer by ablation, wherein the heating in step (b) is adapted to provide an energy density of less than 6.4 J/mm².

2. The method according to claim 1, wherein the layer comprising graphene oxide is heated by laser irradiation at a laser output power of at least 0.04 W.

3. The method according to claim 1, wherein the layer comprising graphene oxide is heated by laser irradiation at a laser output power of at least 0.058 W.

4. The method according to claim 1, wherein the heating in step (b) is carried out at a beam speed 0.1 m/s or less.

5. The method according to claim 1, wherein the heating in step (b) is carried out at a beam speed of 0.04 m/s or less.

6. The method according to claim 1, wherein the heating in step (b) provides a laser output power of at least 0.036 W and is carried out at a beam speed of 0.01 m/s or less.

7. The method according to claim 1, wherein the heating in step (b) provides a laser output power of at least 0.05 W and is carried out at a beam speed of 0.02 m/s or less.

8. The method according to claim 1, wherein the layer is exposed to heating in step (b) of an exposure time of less than 15 ms.

9. The method according to claim 1, wherein the thickness of the layer obtained in step (a) is in the range of from 10 μm to 100 μm.

10. (canceled)

11. (canceled)

12. The method according to claim 1, wherein at least a region of the layer comprising graphene resulting from step (b) has a thickness in the range of from 1 to 10 nm.

13. A graphene layer obtainable by the method according to claim 12.

14. An optoelectronic device comprising a conductive graphene layer obtainable by the method according to claim 12.

15. An electronic device comprising a conductive graphene layer obtainable by the method according claim 12.
